(19) United States
(12) Patent Application Publication
(10) Pub. No.: US 2025/0323623 A1
(43) Pub. Date: Oct. 16, 2025

(54) ACOUSTIC WAVE APPARATUS

(71) Applicant: Murata Manufacturing Co., Ltd., Nagaokakyo-shi (JP)

(72) Inventors: Yasumasa TANIGUCHI, Nagaokakyo-shi (JP); Hideki IWAMOTO, Nagaokakyo-shi (JP); Masanori OTAGAWA, Nagaokakyo-shi (JP); Akira MICHIGAMI, Nagaokakyo-shi (JP)

(21) Appl. No.: 19/250,822

(22) Filed: Jun. 26, 2025

Related U.S. Application Data
(63) Continuation of application No. PCT/JP2023/045082, filed on Dec. 15, 2023.

(30) Foreign Application Priority Data
Dec. 27, 2022 (JP) 2022-209880

(51) Int. Cl. H03H 9/25; H03H 9/02; H03H 9/64

(52) U.S. Cl. CPC H03H 9/25; H03H 9/02574; H03H 9/6483

(57) ABSTRACT

An acoustic wave apparatus includes a piezoelectric substrate including a piezoelectric layer including first and second principal surfaces opposed to each other, first and second IDT electrodes directly or indirectly on the first principal surface, and first and second dielectric films on at least one of the first and second principal surfaces. A portion of the piezoelectric substrate including the first IDT electrode, the first IDT electrode, and the first dielectric film define a first acoustic wave resonator. A portion of the piezoelectric substrate including the second IDT electrode, the second IDT electrode, and the second dielectric film define a second acoustic wave resonator. Each of the first and second dielectric films includes Li and Ta or Li and Nb. At least one of a piezoelectricity, a direction of polarization, or a crystal structure is different between the first and second dielectric films.

### CROSS REFERENCE TO RELATED APPLICATIONS

This application claims the benefit of priority to Japanese Patent Application No. 2022-209880 filed on Dec. 27, 2022 and is a Continuation Application of PCT Application No. PCT/JP2023/045082 filed on Dec. 15, 2023. The entire contents of each application are hereby incorporated herein by reference.

### BACKGROUND OF THE INVENTION

### 1. Field of the Invention

The present invention relates to acoustic wave apparatuses each including multiple acoustic wave resonators.

### 2. Description of the Related Art

Acoustic wave apparatuses including multiple acoustic wave resonators have heretofore been widely used in filters of cellular phones and the like. Japanese Unexamined Patent Application Publication No. 2008-067289 discloses an example of an acoustic wave device as an acoustic wave resonator. In this acoustic wave device, a dielectric is provided on a piezoelectric substrate. Comb-shaped electrodes are provided on the dielectric. An electromechanical coupling coefficient in the acoustic wave device varies by changing a film thickness of the dielectric. In addition, Japanese Unexamined Patent Application Publication No. 2008-067289 shows an example of a filter including the above-described acoustic wave device.

It is possible to adjust a fractional band width of an acoustic wave resonator by adjusting the electromechanical coupling coefficient of the acoustic wave resonator. Note that Japanese Unexamined Patent Application Publication No. 2008-067289 discloses a silicon oxide film and an aluminum oxide film as examples of the dielectric provided between the piezoelectric substrate and the comb-shaped electrodes. Nonetheless, the permittivities of the silicon oxide film and the aluminum oxide film are relatively small. For this reason, in an attempt to obtain a desired capacitance with the acoustic wave device of Japanese Unexamined Patent Application Publication No. 2008-067289, it is necessary to increase the size of the acoustic wave device. Accordingly, the entire filter tends to be increased in size as well.

### SUMMARY OF THE INVENTION

Example embodiments of the present invention provide acoustic wave apparatuses in each of which a fractional band width of each acoustic wave resonator is able to be easily adjusted without an increase in size.

An acoustic wave apparatus according to an example embodiment of the present invention includes a piezoelectric substrate including a piezoelectric layer including a first principal surface and a second principal surface opposed to each other, a first IDT electrode and a second IDT electrode directly or indirectly on the first principal surface of the piezoelectric layer, and a first dielectric film and a second dielectric film on at least one of the first principal surface or the second principal surface of the piezoelectric layer. A portion of the piezoelectric substrate including the first IDT electrode, the first IDT electrode, and the first dielectric film define a first acoustic wave resonator. A portion of the piezoelectric substrate including the second IDT electrode, the second IDT electrode, and the second dielectric film define a second acoustic wave resonator. Each of the first dielectric film and the second dielectric film includes Li and Ta or includes Li and Nb. At least one of a piezoelectricity, a direction of polarization, or a crystal structure is different between the first dielectric film and the second dielectric film.

With acoustic wave apparatuses according to example embodiments of the present invention, a fractional band width of each acoustic wave resonator is able to be easily be adjusted without an increase in size.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of an acoustic wave apparatus according to a first example embodiment of the present invention.

FIG. 2 is a schematic elevational cross-sectional view showing a portion of each of a first acoustic wave resonator and a second acoustic wave resonator in the first example embodiment of the present invention.

FIG. 3 is a schematic elevational cross-sectional view showing a portion of an acoustic wave resonator according to a reference example.

FIG. 4 is a diagram showing a relationship between the thicknesses of a first dielectric film of the first acoustic wave resonator and a second dielectric film of the second acoustic wave resonator and a fractional band width in the first example embodiment of the present invention, and a fractional band width of the acoustic wave resonator of the reference example.

FIG. 5 is a diagram showing a relationship between the thicknesses of the first dielectric film of the first acoustic wave resonator and the second dielectric film of the second acoustic wave resonator and an electrostatic capacitance in the first example embodiment of the present invention, and an electrostatic capacitance of the acoustic wave resonator of the reference example.

FIG. 6 is a schematic plan view of the first acoustic wave resonator in the first example embodiment of the present invention.

FIG. 7 is a schematic elevational cross-sectional view showing a portion of each of a first acoustic wave resonator and a second acoustic wave resonator in a second example embodiment of the present invention.

FIG. 8A is a schematic elevational cross-sectional view of a first acoustic wave resonator in a third example embodiment of the present invention, and FIG. 8B is a schematic elevational cross-sectional view of a second acoustic wave resonator in the third example embodiment of the present invention.

FIG. 9A is a schematic elevational cross-sectional view of a first acoustic wave resonator in a fourth example embodiment of the present invention, and FIG. 9B is a schematic elevational cross-sectional view of a second acoustic wave resonator in the fourth example embodiment of the present invention.

FIG. 10A is a schematic elevational cross-sectional view of a first acoustic wave resonator in a fifth example embodiment of the present invention, and FIG. 10B is a schematic elevational cross-sectional view of a second acoustic wave resonator in the fifth example embodiment of the present invention.

FIG. 11 is a schematic diagram of an acoustic wave apparatus according to a sixth example embodiment of the present invention.

### DETAILED DESCRIPTION OF THE EXAMPLE EMBODIMENTS

The present invention will be clarified below by describing specific example embodiments of the present invention with reference to the drawings.

The respective example embodiments described in the present specification are merely examples and partial replacement or combination of features and structures between different example embodiments is possible.

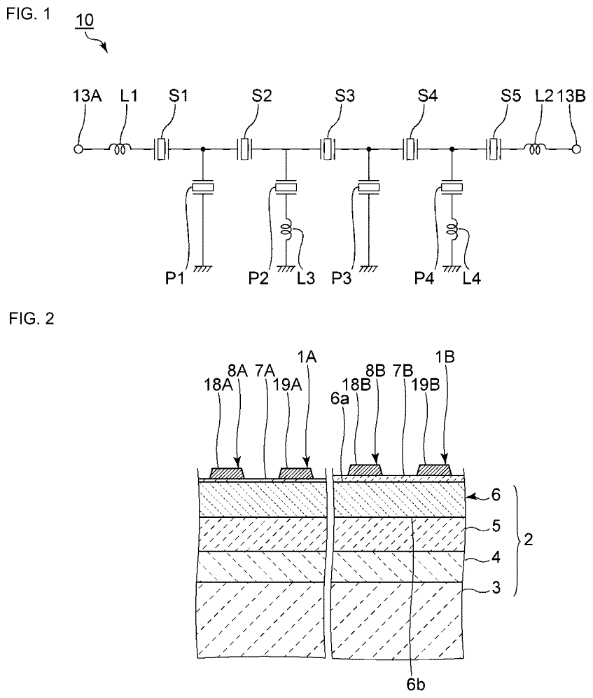

FIG. 1 is a circuit diagram of an acoustic wave apparatus according to a first example embodiment of the present invention.

An acoustic wave apparatus 10 of the present example embodiment is a ladder filter, for example. The acoustic wave apparatus 10 includes a first signal terminal 13A, a second signal terminal 13B, multiple inductors, multiple series arm resonators, and multiple parallel arm resonators. In the present example embodiment, each of the multiple series arm resonators and the multiple parallel arm resonators is an acoustic wave resonator, for example. Specifically, for example, the acoustic wave apparatus 10 is a band-pass filter for Band 41. To be more specific, for example, the acoustic wave apparatus 10 is a transmission filter and the pass band of the acoustic wave apparatus 10 is in a range from about 2496 MHz to about 2690 MHz.

Nonetheless, the pass band of the acoustic wave apparatus 10 is not limited to the above-described range. Moreover, the acoustic wave apparatuses according to example embodiments of the present invention are not limited to the transmission filter and may be a reception filter instead. The acoustic wave apparatuses according to example embodiments of the present invention are not limited to a single filter and may instead be a multiplexer that includes multiple filters. The acoustic wave apparatuses according to example embodiments of the present invention only need to include multiple acoustic wave resonators. The acoustic wave apparatus 10 of the present example embodiment includes a first acoustic wave resonator and a second acoustic wave resonator. Specific configurations of the first acoustic wave resonator and the second acoustic wave resonator will be described below.

FIG. 2 is a schematic elevational cross-sectional view showing a portion of each of the first acoustic wave resonator and the second acoustic wave resonator in the first example embodiment. Although FIG. 2 schematically shows a first acoustic wave resonator 1A and a second acoustic wave resonator 1B in an arranged manner, the layout of the first acoustic wave resonator 1A and the second acoustic wave resonator 1B is not limited to a particular layout.

The first acoustic wave resonator 1A and the second acoustic wave resonator 1B share a piezoelectric substrate 2. Moreover, the first acoustic wave resonator 1A includes a first IDT electrode 8A. The second acoustic wave resonator 1B includes a second IDT electrode 8B. The first IDT electrode 8A and the second IDT electrode 8B are provided on the piezoelectric substrate 2. An acoustic wave is excited by applying an alternating-current voltage to the first IDT electrode 8A. The same applies to the second IDT electrode 8B.

Here, each of the first IDT electrode 8A and the second IDT electrode 8B includes multiple electrode fingers. FIG. 2 shows a neighborhood of a pair of electrode fingers in the first IDT electrode 8A and a neighborhood of a pair of electrode fingers in the second IDT electrode 8B.

The first IDT electrode 8A includes laminated metal films. Specifically, the first IDT electrode 8A includes, for example, a layer structure in which a Ti layer, an Al layer, and a Ti layer are laminated in this order from the piezoelectric substrate 2 side. The second IDT electrode 8B also includes the same laminated metal films as those of the first IDT electrode 8A. Nevertheless, the materials of the first IDT electrode 8A and the second IDT electrode 8B are not limited to the above-described materials. Alternatively, the first IDT electrode 8A and the second IDT electrode 8B may include a single layer of a metal film, for example.

The piezoelectric substrate 2 is a multilayer substrate that includes a piezoelectric layer 6. In other words, the piezoelectric substrate 2 is a substrate that has piezoelectricity. In the present example embodiment, the piezoelectric layer 6 includes, for example, a piezoelectric single crystal layer made of LiNbO₃. The crystal structure of the piezoelectric layer 6 includes, for example, LiNbO₃. Nonetheless, the piezoelectric layer 6 may instead be a piezoelectric single crystal layer made of LiTaO₃, for example. The piezoelectric layer 6 preferably includes Li and Nb or includes Li and Ta, for example.

In addition, the piezoelectric substrate 2 includes a support substrate 3, a high acoustic velocity film 4 as a high acoustic velocity material layer, and a low acoustic velocity film 5. The support substrate 3, the high acoustic velocity film 4, the low acoustic velocity film 5, and the piezoelectric layer 6 are laminated in this order. The high acoustic velocity material layer is a layer having a relatively high acoustic velocity. To be more precise, the acoustic velocity of a bulk wave propagating through the high acoustic velocity material layer is higher than the acoustic velocity of an acoustic wave propagating through the piezoelectric layer 6. On the other hand, the low acoustic velocity film 5 is a layer having a relatively low acoustic velocity. To be more precise, the acoustic velocity of a bulk wave propagating through the low acoustic velocity film 5 is lower than the acoustic velocity of the bulk wave propagating through the piezoelectric layer 6.

In the present example embodiment, for example, silicon is used as the material of the support substrate 3. Silicon nitride, for example, is used as the material of the high acoustic velocity film 4. Silicon oxide, for example, is used as the material of the low acoustic velocity film 5. The materials of the support substrate 3, the high acoustic velocity film 4, and the low acoustic velocity film 5 are not limited to the above-described materials. Alternatively, the piezoelectric substrate 2 may be a substrate that includes only the piezoelectric layer 6.

The piezoelectric layer 6 includes a first principal surface 6a and a second principal surface 6b. The first principal surface 6a and the second principal surface 6b are located opposite to each other. Of the first principal surface 6a and the second principal surface 6b, the second principal surface 6b is located on the support substrate 3 side. The first principal surface 6a is provided with a first dielectric film 7A. The above-described first IDT electrode 8A is provided on the first dielectric film 7A. Accordingly, the first IDT electrode 8A is indirectly provided on the first principal surface 6a with the first dielectric film 7A interposed therebetween. A portion of the piezoelectric substrate 2 provided with the first IDT electrode 8A, the first IDT electrode 8A, and the first dielectric film 7A define the first acoustic wave resonator 1A.

In addition, the first principal surface 6a of the piezoelectric layer 6 is provided with a second dielectric film 7B. Here, on the first principal surface 6a, the position of a portion where the second dielectric film 7B is provided and the position of a portion where the first dielectric film 7A is provided are different from each other. The above-described second IDT electrode 8B is provided on the second dielectric film 7B. Accordingly, the second IDT electrode 8B is indirectly provided on the first principal surface 6a with the second dielectric film 7B interposed therebetween. A portion of the piezoelectric substrate 2 provided with the second IDT electrode 8B, the second IDT electrode 8B, and the second dielectric film 7B define the second acoustic wave resonator 1B.

In the present example embodiment, the first dielectric film 7A is, for example, a LiNbOₓ film, where x is a freely-selected positive number. The second dielectric film 7B is, for example, a LiNbO_{y} film, where y is a freely-selected positive number. That is, the first dielectric film 7A and the second dielectric film 7B are oxide films including Li and Nb, for example.

Physical properties of the first dielectric film 7A and the second dielectric film 7B are as shown in Table 1. Here, although the second dielectric film 7B is not a single crystal film, Table 1 shows values corresponding to those of a single crystal as a Young's modulus, a Poisson's ratio, and a density thereof.

TABLE 1

| | first | |
|---|---|---|
| | dielectric film | second dielectric film |
| Young's modulus | 158 | 170 |
| [GPa] | | |
| Poisson's ratio | 0.24 | 0.25 |
| density [g/cm³] | 4.408 | 4.64 |
| permittivity | 53 | 53 |
| piezoelectricity | none | 50% of a LiNbO₃ single |
| | | crystal of a LiNbO₃ type |
| | | (including a portion where a |
| | | direction of polarization |
| | | becomes an opposite |
| | | direction to that of the |
| | | piezoelectric layer) |
| crystal direction | inverted about | inverted about the C-axis |
| | the C-axis | |

As shown in Table 1, the piezoelectricity of the first dielectric film f 7A and the piezoelectricity of the second dielectric film 7B are different from each other. Specifically, the first dielectric film 7A has no piezoelectricity, whereas the second dielectric film 7B has piezoelectricity in the present example embodiment. Nevertheless, even in the case where the first dielectric film 7A has piezoelectricity, the piezoelectricity of the first dielectric film 7A and the piezoelectricity of the second dielectric film 7B may be different from each other. Alternatively, the direction of polarization of the first dielectric film 7A and the direction of polarization of the second dielectric film 7B may be different from each other. This is not limited to the configurations in which the direction of polarization of the entire first dielectric film 7A and the direction of polarization of the entire second dielectric film 7B are different from each other. Specifically, the first dielectric film 7A and the second dielectric film 7B may include portions with the direction of polarizations being different from each other. In the present example embodiment, the crystal structures of the first dielectric film 7A and the second dielectric film 7B are also different from each other. To be more precise, the state where the crystal structures are different from each other means that one of the crystal structures is a single-crystalline structure and the other crystal structure is a polycrystalline structure, or that atoms included in the crystal structures are different from each other, for example.

The materials of the first dielectric film 7A and the second dielectric film 7B are not limited to the above-described materials. For example, the first dielectric film 7A may be a LiTaOₓ film. The second dielectric film 7B may be a LiTaO_{y} film. Here, x and y are freely-selected positive numbers. Moreover, the first dielectric film 7A and the second dielectric film 7B are not limited to oxides. Alternatively, the first dielectric film 7A may include Li and Ta and the second dielectric film 7B may include Li and Nb, for example. The first dielectric film 7A may include Li and Nb and the second dielectric film 7B may include Li and Ta, for example.

It is possible to adjust the fractional band width of the first acoustic wave resonator 1A by adjusting the thickness of the first dielectric film 7A. Likewise, it is possible to adjust the fractional band width of the second acoustic wave resonator 1B by adjusting the thickness of the second dielectric film 7B. Here, the fractional band width can be expressed as (|fr−fa|/fr)×100[%], where fr is a resonant frequency and fa is an anti-resonant frequency. In the acoustic wave apparatus 10, the thicknesses of the first dielectric film 7A and the second dielectric film 7B are different from each other. Nonetheless, the thickness of the first dielectric film 7A may be equal or substantially equal to the thickness of the second dielectric film 7B.

The present example embodiment has the following configurations 1) and 2). 1) each of the first dielectric film 7A and the second dielectric film 7B includes Li and Ta or includes Li and Nb, and 2) at least one of the piezoelectricity, the direction of polarization, or the crystal structure is different between the first dielectric film 7A and the second dielectric film 7B. As such, the fractional band width of each acoustic wave resonator of the acoustic wave apparatus 10 can easily be adjusted without causing an increase in size of the acoustic wave apparatus 10. This advantageous effect will be described below in detail.

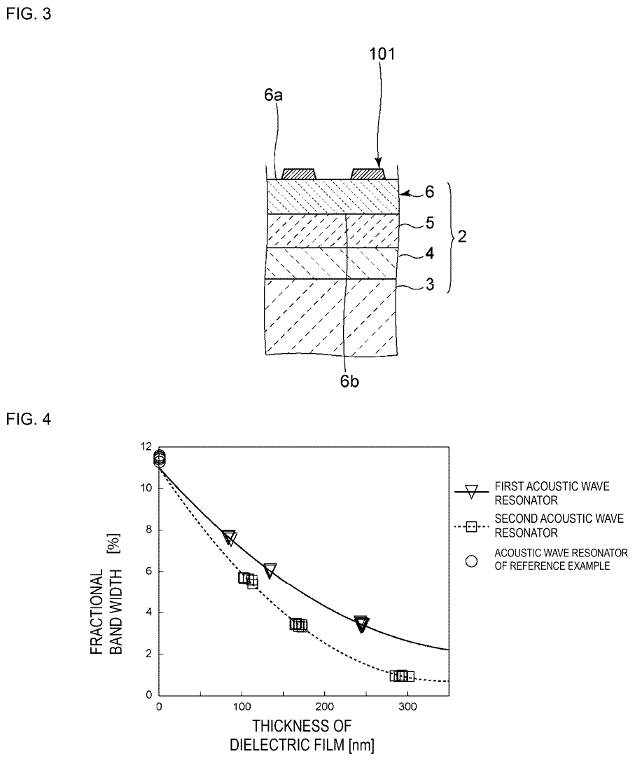

Multiple first acoustic wave resonators 1A including first dielectric films 7A having different thicknesses from one another were prepared. Likewise, multiple second acoustic wave resonators 1B including films second dielectric 7B having different thicknesses from one another were prepared. In addition, an acoustic wave resonator 101 of a reference example shown in FIG. 3 was prepared. The acoustic wave resonator 101 of the reference example is different from the first acoustic wave resonators 1A and the second acoustic wave resonators 1B in that the acoustic wave resonator 101 neither includes the first dielectric film 7A nor the second dielectric film 7B. Here, multiple acoustic wave resonators of the reference example having the same or substantially the same design parameters were prepared. The design parameters of the prepared first acoustic wave resonators 1A are as follows. Here, a wavelength defined by an electrode finger pitch of an IDT electrode is denoted as A. The electrode finger pitch is a center-to-center distance between electrode fingers that are connected to electric potentials being different from each other and are located adjacent to each other. To be more precise, when the electrode finger pitch is denoted as p, the wavelength λ is defined as λ=2p.
Support substrate 3: material . . . Si
High acoustic velocity film 4: material . . . SiN, thickness . . . about 0.9 μm
Low acoustic velocity film 5: material . . . SiO₂, thickness . . . about 1 μm
Piezoelectric layer 6: material . . . LiNbO₃, thickness . . . about 1 μm
First dielectric film 7A: material . . . LiNbOₓ, thickness . . . about 90 nm, about 130 nm, or about 240 nm
First IDT electrode 8A: layer structure . . . Ti layer/Al layer/Ti layer from the piezoelectric layer 6 side, thickness . . . about 4 nm/about 400 nm/about 30 nm from the piezoelectric layer 6 side, duty ratio . . . about 0.5
Wavelength λ: about 4 μm

The design parameters of the prepared second acoustic wave resonators 1B are the same or substantially the same as the design parameters of the first acoustic wave resonators 1A except for the following point. Design parameters of the second IDT electrode 8B are the same or substantially the same as the design parameters of the first IDT electrode 8A.
Second dielectric film 7B: material. LiNbO_{y}, thickness . . . about 100 nm, about 160 nm, or about 290 nm

The design parameters of the prepared acoustic wave resonators 101 of the reference example are the same or substantially the same as the design parameters of the first acoustic wave resonators 1A except that each acoustic wave resonator 101 does not include the first dielectric film 7A. Design parameters of the IDT electrode of each acoustic wave resonator 101 are the same or substantially the same as the design parameters of the first IDT electrode 8A.

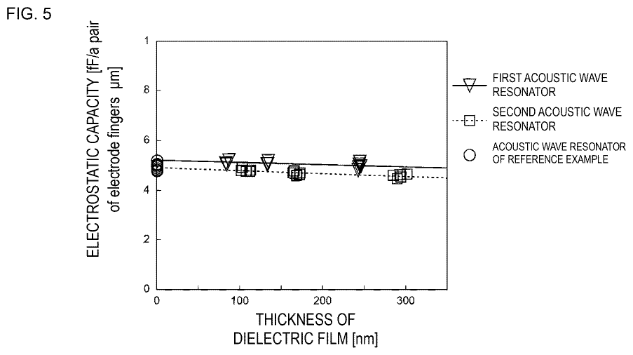

The fractional band width and electrostatic capacitance of each of the prepared acoustic wave resonators are shown in FIG. 4 and FIG. 5. FIG. 5 indicates the electrostatic capacitance as an electrostatic capacitance for each portion where a pair of electrode fingers in an IDT electrode is located.

FIG. 4 is a diagram showing a relationship between the thicknesses of the first dielectric film of the first acoustic wave resonator and the second dielectric film of the second acoustic wave resonator and the fractional band width in the first example embodiment, and the fractional band width of the acoustic wave resonator of the reference example. FIG. 5 is a diagram showing a relationship between the thicknesses of the first dielectric film of the first acoustic wave resonator and the second dielectric film of the second acoustic wave resonator and the electrostatic capacitance in the first example embodiment, and the electrostatic capacitance of the acoustic wave resonator of the reference example. The horizontal axes in FIG. 4 and FIG. 5 indicate the thickness of the first dielectric film 7A in the case of the first acoustic wave resonator 1A and the thickness of the second dielectric film 7B in the case of the second acoustic wave resonator 1B.

As shown in FIG. 4, as the thickness of the first dielectric film 7A increases, the value of the fractional band width in the first acoustic wave resonator 1A becomes smaller. Likewise, as the thickness of the second dielectric film 7B increases, the value of the fractional band width in the second acoustic wave resonator 1B becomes smaller. Here, in the acoustic wave resonator 101 of the reference example, the thickness of the dielectric film corresponds to 0. Accordingly, the values of the fractional band width in the first acoustic wave resonator 1A and the second acoustic wave resonator 1B are smaller than the value of the fractional band width in the acoustic wave resonator 101 of the reference example.

Here, the tendency of change in fractional band width in the first acoustic wave resonator 1A relative to the change in thickness of the first dielectric film 7A and the tendency of change in fractional band width in the second acoustic wave resonator 1B relative to the change in thickness of the second dielectric film 7B are different from each other. Accordingly, in each of the acoustic wave resonators of the acoustic wave apparatus 10, it is possible to adjust the fractional band width not only by adjusting the thickness of the dielectric films but also by determining whether the first dielectric film 7A or the second dielectric film 7B is used in each acoustic wave resonator. Thus, in the acoustic wave apparatus 10, it is possible to adjust the fractional band width easily for each acoustic wave resonator.

For example, the fractional band width of the first acoustic wave resonator 1A can be adjusted with high accuracy, when the first dielectric film 7A is selected to reduce the inclination of change in fractional band width relative to the thickness of the first dielectric film 7A in the vicinity of a desired fractional band width in the first acoustic wave resonator 1A. Then, the fractional band width of the second acoustic wave resonator 1B can be adjusted with high accuracy, when the second dielectric film 7B is selected to reduce the inclination of change in fractional band width relative to the thickness of the second dielectric film 7B in the vicinity of a desired fractional band width in the second acoustic wave resonator 1B. As described above, it is possible to adjust the fractional band width in each acoustic wave resonator of the acoustic wave apparatus 10 easily and at high accuracy.

On the other hand, as shown in FIG. 5, it is apparent that the electrostatic capacitance of the first acoustic wave resonator 1A hardly varies even when the thickness of the first dielectric film 7A is changed. Likewise, it is apparent that the electrostatic capacitance of the second acoustic wave resonator 1B hardly varies even when the thickness of the second dielectric film 7B is changed. Moreover, the electrostatic capacitances of the first acoustic wave resonator 1A and the second acoustic wave resonator 1B are equivalent to the electrostatic capacitance of the acoustic wave resonator 101 of the reference example. That is, in the present example embodiment, even when the first dielectric film 7A and the second dielectric film 7B are provided on the piezoelectric layer 6 as shown in FIG. 2, the electrostatic capacitances thereof are hardly reduced.

For example, the permittivity of a dielectric film is low when the dielectric film is made of silicon oxide, aluminum oxide, or the like as in the related art. For this reason, the electrostatic capacitance of a multilayer body including a piezoelectric layer and the dielectric film is low. As such, when the dielectric film is provided, it is necessary to increase the area of the multilayer body including the piezoelectric layer and the dielectric film in order to obtain a desired electrostatic capacitance.

On the other hand, in the present example embodiment, the electrostatic capacitances of the first acoustic wave resonator 1A and the second acoustic wave resonator 1B are hardly reduced even when the first dielectric film 7A and the second dielectric film 7B are provided on the piezoelectric layer 6. The same applies when the thicknesses of the first dielectric film 7A and the second dielectric film 7B are adjusted. Accordingly, it is possible to easily adjust the fractional band widths in the first acoustic wave resonator 1A and the second acoustic wave resonator 1B of the acoustic wave apparatus 10 without an increase in size of the acoustic wave apparatus 10.

The configuration of the present example embodiment will be described further in detail below.

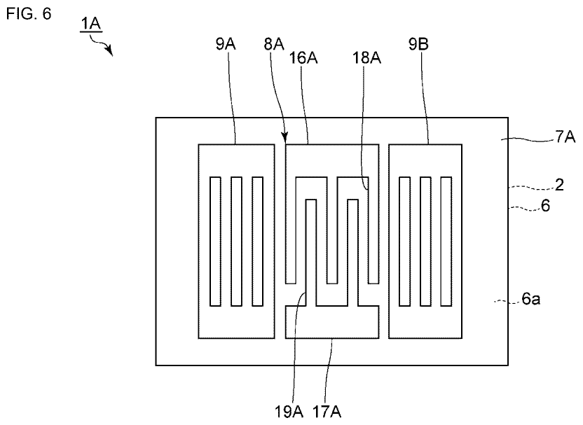

FIG. 6 is a schematic plan view of the first acoustic wave resonator in the first example embodiment. FIG. 6 omits wiring connected to the first acoustic wave resonator 1A.

The first IDT electrode 8A includes a first busbar 16A, a second busbar 17A, and the above-described multiple electrode fingers. The first busbar 16A and the second busbar 17A are opposed to each other. To be specific, the multiple electrode fingers include multiple first electrode fingers 18A and multiple second electrode fingers 19A. One end of each of the multiple first electrode fingers 18A is connected to the first busbar 16A. One end of each of the multiple second electrode fingers 19A is connected to the second busbar 17A. The multiple first electrode fingers 18A and the multiple second electrode fingers 19A are interdigitated with one another. Each first electrode finger 18A and each second electrode finger 19A are connected to the electric potentials that are different from each other. In the present example embodiment, when the direction of extension of the multiple first electrode fingers 18A and the multiple second electrode fingers 19A is defined as an electrode finger extending direction, the electrode finger extending direction is orthogonal or substantially orthogonal to an acoustic wave propagating direction.

The first acoustic wave resonator 1A includes a pair of reflectors 9A and 9B. The reflectors 9A and 9B are provided on the first principal surface 6a of the piezoelectric layer 6. To be more precise, in the present example embodiment, each reflector is indirectly provided on the first principal surface 6a with the first dielectric film 7A interposed therebetween. The reflector 9A and the reflector 9B are opposed to each other with the first IDT electrode 8A interposed therebetween in the acoustic wave propagating direction. The first acoustic wave resonator 1A is, for example, a surface acoustic wave resonator.

Likewise, the second acoustic wave resonator 1B shown in FIG. 2 is, for example, a surface acoustic wave resonator as well. The second IDT electrode 8B includes a pair of busbars, multiple first electrode fingers 18B, and multiple second electrode fingers 19B. The second acoustic wave resonator 1B includes a pair of reflectors. Each acoustic wave resonator other than the first acoustic wave resonator 1A and the second acoustic wave resonator 1B in the acoustic wave apparatus 10 also includes an IDT electrode and a pair of busbars.

Each of the electrode fingers of the first IDT electrode 8A and the second IDT electrode 8B includes two surfaces opposed to each other in the thickness direction thereof, and side surfaces. The side surfaces are connected to the two surfaces. In the present example embodiment, the side surfaces of each electrode finger extend in an inclined manner with respect to the normal direction to the first principal surface 6a of the piezoelectric layer 6. Nonetheless, the side surfaces of each electrode finger may extend parallel or substantially parallel to the normal direction to the first principal surface 6a.

A circuit configuration of the present example embodiment will be described below. As shown in FIG. 1, the multiple series arm resonators of the acoustic wave apparatus 10 include a series arm resonator S1, a series arm resonator S2, a series arm resonator S3, a series arm resonator S4, and a series arm resonator S5. The series arm resonator S1, the series arm resonator S2, the series arm resonator S3, the series arm resonator S4, and the series arm resonator S5 are connected in series to one another in this order between the first signal terminal 13A and the second signal terminal 13B.

In the present example embodiment, the second signal terminal 13B is, for example, an antenna terminal. The antenna terminal is connected to an antenna. Nonetheless, the second signal terminal 13B does not have to be the antenna terminal.

The multiple parallel arm resonators of the acoustic wave apparatus 10 include a parallel arm resonator P1, a parallel arm resonator P2, a parallel arm resonator P3, and a parallel arm resonator P4. The parallel arm resonator P1 is connected between a ground potential and a connecting point between the series arm resonator S1 and the series arm resonator S2. The parallel arm resonator P2 is connected between the ground potential and a connecting point between the series arm resonator S2 and the series arm resonator S3. The parallel arm resonator P3 is connected between the ground potential and a connecting point between the series arm resonator S3 and the series arm resonator S4. The parallel arm resonator P4 is connected between the ground potential and a connecting point between the series arm resonator S4 and the series arm resonator S5.

The multiple inductors of the acoustic wave apparatus 10 include an inductor L1, an inductor L2, an inductor L3, and an inductor L4. The inductor L1 is connected between the first signal terminal 13A and the series arm resonator S1. The inductor L2 is connected between the series arm resonator S5 and the second signal terminal 13B. The inductor L3 is connected between the parallel arm resonator P2 and the ground potential. The inductor L4 is connected between the parallel arm resonator P4 and the ground potential.

The circuit configuration of the acoustic wave apparatus 10 is not limited to the above-described configuration. The acoustic wave apparatus 10 does not always have to include the multiple inductors. When the acoustic wave apparatus according to the present invention is a ladder filter, for example, the acoustic wave apparatus only needs to include at least one series arm resonator and at least one parallel arm resonator.

In the present example embodiment, the first acoustic wave resonator 1A is the parallel arm resonator P1. The second acoustic wave resonator 1B is the parallel arm resonator P2. Nevertheless, the layout of the first acoustic wave resonator 1A and the second acoustic wave resonator 1B is not limited to the above-described layout. The first acoustic wave resonator 1A and the second acoustic wave resonator 1B only need to be any of the acoustic wave resonators in the acoustic wave apparatus 10.

The acoustic wave apparatus 10 includes one first acoustic wave resonator 1A and one second acoustic wave resonator 1B. Here, the acoustic wave apparatus 10 may include multiple first acoustic wave resonators 1A. Likewise, the acoustic wave apparatus 10 may include multiple second acoustic wave resonators 1B.

As described above, the pass band of the acoustic wave apparatus 10 is, for example, in the range from about 2496 MHz to about 2690 MHz. Accordingly, the acoustic wave apparatus 10 is a wideband filter. Moreover, the low range side of the pass band of the acoustic wave apparatus is adjacent to a Wi-Fi band. In this case, the low range side of the pass band preferably has high steepness. In the present specification, the high steepness means that an amount of change in frequency is small relative to a certain change in attenuation in the vicinity of a frequency at an end portion of the pass band. The fractional band width of the parallel arm resonator has a large impact on the steepness on the low range side of the pass band. Specifically, the steepness on the low range side of the pass band can be increased by reducing the value of the fractional band width of the parallel arm resonator.

In the above-described case, the first acoustic wave resonator 1A and the second acoustic wave resonator 1B are preferably parallel arm resonators as in the present example embodiment. This configuration can easily reduce the values of the fractional band widths of the parallel arm resonators, which are the first acoustic wave resonator 1A and the second acoustic wave resonator 1B. Accordingly, the steepness on the low range side of the pass band can be increased easily. One of the first acoustic wave resonator 1A and the second acoustic wave resonator 1B is preferably a parallel arm resonator which has the highest resonant frequency among the multiple parallel arm resonators of the acoustic wave apparatus 10. This configuration can easily and effectively increase the steepness on the low range side of the pass band. Accordingly, the acoustic wave apparatus 10 can more reliably reduce the chance of passage of a signal in the Wi-Fi band or the like that is outside the pass band.

In addition, in the present example embodiment, either the first dielectric film 7A or the second dielectric film 7B is used in the acoustic wave resonator that reduces the value of the fractional band width among the multiple acoustic wave resonators in the acoustic wave apparatus 10. Specifically, the acoustic wave apparatus 10 includes the first acoustic wave resonator 1A, the second acoustic wave resonator 1B, and the acoustic wave resonators other than the first acoustic wave resonator 1A and the second acoustic wave resonator 1B. For example, the acoustic wave apparatus 10 may include the acoustic wave resonator 101 of the reference example. The acoustic wave apparatus 10 includes the first acoustic wave resonator 1A and the second acoustic wave resonator 1B having small values of the fractional band width, and multiple acoustic wave resonators having large values of the fractional band width. In this way, the acoustic wave apparatus 10 can achieve the widening of the pass band and the increase in the steepness at the same time.

In the meantime, for example, when both of the first dielectric film 7A and the second dielectric film 7B are lithium niobate films and the crystal structures of both of the dielectric films are different from each other, both of the dielectric films may be any of the following examples. Specifically, for example, both of the dielectric films may be any of ilmenite lithium niobate, LiNb₃O₈, Li₃NbO₄, and LiNbO₂.

When each of the first dielectric film 7A and the second dielectric film 7B has a crystal structure with Euler angles (ϕ, θ, ψ) and the directions of polarization of both of the dielectric films are different from each other, the values θ in the Euler angles of both of the dielectric films only need to be different from each other, for example.

Here, the structure of each of the first dielectric film 7A and the second dielectric film 7B does not always have to be homogeneous. The first dielectric film 7A or the second dielectric film 7B may be a film in which the crystal structure, a physical property value, or the direction of polarization varies in the thickness direction, for example. When one of the first dielectric film 7A and the second dielectric film 7B has an inhomogeneous structure and the other has a homogeneous structure, at least one of the piezoelectricity, the direction of polarization, or the crystal structure is different between the first dielectric film 7A and the second dielectric film 7B. Alternatively, for example, when both of the dielectric films have inhomogeneous structures and the crystal structure included in one of the dielectric films is a crystal structure that is not included in the other dielectric film, the crystal structure is different between the first dielectric film 7A and the second dielectric film 7B.

It is preferable that at least one of the first dielectric film 7A or the second dielectric film 7B include Li and Nb and the piezoelectric layer 6 include Li and Nb, for example. When the first dielectric film 7A includes Li and Nb, the crystallinity of the first dielectric film 7A can easily be improved by forming the first dielectric film 7A on the piezoelectric layer 6 by deposition. The same applies to the case where the second dielectric film 7B includes Li and Nb, for example.

Alternatively, it is preferable that at least one of the first dielectric film 7A or the second dielectric film 7B include Li and Ta and the piezoelectric layer 6 include Li and Ta, for example. In this case as well, the crystallinity of the dielectric film including Li and Ta of the first dielectric film 7A and the second dielectric film 7B can easily be improved.

Here, when the first dielectric film 7A includes Li and Ta, the first dielectric film 7A may be LiTaOₓ, where x is a freely-selected positive number, for example. When the second dielectric film 7B includes Li and Ta, the second dielectric film 7B may be LiTaO_{y}, where y is a freely-selected positive number, for example. Nonetheless, as described above, the first dielectric film 7A and the second dielectric film 7B are not limited to oxide films.

The thickness of the first dielectric film 7A and the thickness of the second dielectric film 7B are preferably different from each other as in the present example embodiment. In this case, the fractional band width in each of the first acoustic wave resonator 1A and the second acoustic wave resonator 1B can more reliably be adjusted to a desired value.

In the piezoelectric substrate 2 of the present example embodiment shown in FIG. 2, the high acoustic velocity film 4, the low acoustic velocity film 5, and the piezoelectric layer 6 are laminated in this order. As such, the energy of an acoustic wave can be effectively confined on the piezoelectric layer 6 side. Although silicon nitride and silicon oxide have been discussed above as the examples of the materials of the high acoustic velocity film 4 and the low acoustic velocity film 5, other materials may also be used for the high acoustic velocity film 4 and the low acoustic velocity film 5. Examples of these materials will be shown below. Examples of the material of the support substrate 3 will also be shown at the same time.

The material of the low acoustic velocity film 5 can be, for example, a dielectric such as glass, silicon oxide, silicon oxynitride, lithium oxide, tantalum oxide, or a compound obtained by adding fluorine, carbon, or boron to silicon oxide, or a material including any of these materials as the principal component. Here, the principal component in the present specification means a component that accounts for more than 50 wt %. The material of the principal component may be present in any of single-crystalline, polycrystalline, and amorphous states or in a state of mixture of these states.

The material of the high acoustic velocity film 4, which is a high acoustic velocity material layer, can also be, for example, a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiAlON, a dielectric such as aluminum oxide, silicon oxynitride, diamond-like carbon (DLC), or diamond, a semiconductor such as silicon, or a material including any of these materials as the principal component. Note that the above-described spinel includes an aluminum compound including oxygen and one or more elements selected from the group consisting of Mg, Fe, Zn, Mn, and the like. Examples of the above-described spinel include MgAl₂O₄, FeAl₂O₄, ZnAl₂O₄, and MnAl₂O₄.

The material of the support substrate 3 can also be, for example, a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or SiAlON, a dielectric such as aluminum oxide, silicon oxynitride, diamond-like carbon (DLC), or diamond, a semiconductor such as silicon, or a material including any of these materials as the principal component. The above-described spinel includes an aluminum compound including oxygen and one or more of Mg, Fe, Zn, Mn, or the like. Examples of the above-described spinel include MgAl₂O₄, FeAl₂O₄, ZnAl₂O₄, and MnAl₂O₄.

The multilayer structure of the piezoelectric substrate is not limited to the above-described structure. For example, the piezoelectric substrate may be a multilayer substrate including a support substrate, a high acoustic velocity film as a high acoustic velocity material layer, and a piezoelectric layer. Alternatively, the high acoustic velocity material layer may be a high acoustic velocity support substrate. In this case, the piezoelectric substrate may be a multilayer substrate including the high acoustic velocity support substrate, a low acoustic velocity film, and the piezoelectric layer, or a multilayer substrate composed of the high acoustic velocity support substrate and the piezoelectric layer. The energy of an acoustic wave can be effectively confined on the piezoelectric layer side in these cases as well.

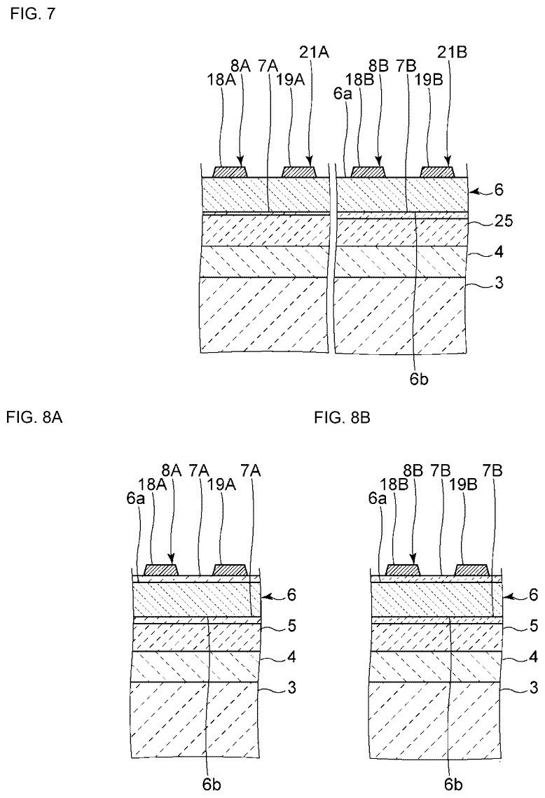

FIG. 7 is a schematic elevational cross-sectional view showing a portion of each of a first acoustic wave resonator and a second acoustic wave resonator in a second example embodiment of the present invention.

In the present example embodiment, the positions of the first dielectric film 7A and the second dielectric film 7B are different from those in the first example embodiment. Except for the above-described point, the acoustic wave apparatus of the present example embodiment has the same or substantially the same configuration as that of the acoustic wave apparatus 10 of the first example embodiment.

The first dielectric film 7A is provided on the second principal surface 6b of the piezoelectric layer 6. The first IDT electrode 8A is directly provided on the first principal surface 6a of the piezoelectric layer 6. The first IDT electrode 8A and the first dielectric film 7A are opposed to each other with the piezoelectric layer 6 interposed therebetween.

Likewise, the second dielectric film 7B is provided on the second principal surface 6b of the piezoelectric layer 6. The second IDT electrode 8B is directly provided on the first principal surface 6a of the piezoelectric layer 6. The second IDT electrode 8B and the second dielectric film 7B are opposed to each other with the piezoelectric layer 6 interposed therebetween.

It is preferable that as in the present example embodiment, both of the first dielectric film 7A and the second dielectric film 7B are provided on the second principal surface 6b of the piezoelectric layer 6 and both of the first IDT electrode 8A and the second IDT electrode 8B be provided directly on the first principal surface 6a of the piezoelectric layer 6. In this case, it is possible to align the crystallinity of the first IDT electrode 8A with the crystallinity of the second IDT electrode 8B. Accordingly, the difference in electric power handling capability between a first acoustic wave resonator 21A and a second acoustic wave resonator 21B can be reduced.

As shown in FIG. 7, the thicknesses of the first dielectric film 7A and the second dielectric film 7B are different from each other. In the meantime, the thickness of a portion where the first dielectric film 7A and a low acoustic velocity film 25 are laminated is equal or substantially equal to the thickness of a portion where the second dielectric film 7B and the low acoustic velocity film 25 are laminated. This is because, in order to equalize the thicknesses of these two portions, the thickness of a portion of the low acoustic velocity film 25 on which the first dielectric film 7A is laminated and the thickness of a portion of the low acoustic velocity film 25 on which the second dielectric film 7B is laminated are set to be different from each other.

Productivity of the acoustic wave apparatus can be improved by equalizing the thicknesses of the above-described two portions. To be more precise, when manufacturing acoustic wave apparatuses, multiple IDT electrodes and the like are formed on a laminate wafer and then the wafer is cut into individual pieces. Thus, the multiple acoustic wave apparatuses are obtained. Multiple piezoelectric substrates are formed by cutting the laminate wafer into the individual pieces. Then, in the case where the two thicknesses are equal, it is easy to set the thickness of the laminate wafer constant. Accordingly, it is easy to form the laminate wafer, so that the productivity of the acoustic wave apparatuses can be improved.

In the present example embodiment as well, each of the first dielectric film 7A and the second dielectric film 7B includes, for example, Li and Ta or includes Li and Nb as with the first example embodiment. Moreover, at least one of the piezoelectricity, the direction of polarization, or the crystal structure is different between the first dielectric film 7A and the second dielectric film 7B. As such, the fractional band width of each acoustic wave resonator of the acoustic wave apparatus can easily be adjusted without causing an increase in size of the acoustic wave apparatus.

Here, the first dielectric film 7A and the second dielectric film 7B may have the same piezoelectricity, the same direction of polarization, and the same crystal structure but different thicknesses, for example. In this case as well, the fractional band width of each acoustic wave resonator of the acoustic wave apparatus can easily be adjusted without causing an increase in size of the acoustic wave apparatus. Nevertheless, at least one of the piezoelectricity, the direction of polarization, or the crystal structure is preferably different between the first dielectric film 7A and the second dielectric film 7B as in the first example embodiment and the second example embodiment. As such, the fractional band width of each acoustic wave resonator can be even more easily adjusted.

FIG. 8A is a schematic elevational cross-sectional view of a first acoustic wave resonator in a third example embodiment of the present invention. FIG. 8B is a schematic elevational cross-sectional view of a second acoustic wave resonator in the third example embodiment.

As shown in FIG. 8A, the present example embodiment is different from the first example embodiment in that the first dielectric films 7A are provided on both of the first principal surface 6a and the second principal surface 6b of the piezoelectric layer 6. As shown in FIG. 8B, the present example embodiment is also different from the first example embodiment in that the second dielectric films 7B are provided on both of the first principal surface 6a and the second principal surface 6b of the piezoelectric layer 6. Except for the above-described points, the acoustic wave apparatus of the present example embodiment has the same or substantially the same configuration as that of the acoustic wave apparatus 10 of the first example embodiment.

The acoustic wave apparatus of the present example embodiment also has the configurations 1) and 2) as with the acoustic wave apparatus 10 of the first example embodiment. Specifically, in the acoustic wave apparatus of the present example embodiment, each of the first dielectric film 7A and the second dielectric film 7B includes Li and Ta or includes Li and Nb, for example. Moreover, at least one of the piezoelectricity, the direction of polarization, or the crystal structure is different between the first dielectric film 7A and the second dielectric film 7B. As such, the fractional band width of each acoustic wave resonator of the acoustic wave apparatus can easily be adjusted without causing an increase in size of the acoustic wave apparatus.

As in the first to third example embodiments, the first dielectric film 7A and the second dielectric film 7B only need to be provided on at least one of the first principal surface 6a or the second principal surface 6b of the piezoelectric layer 6.

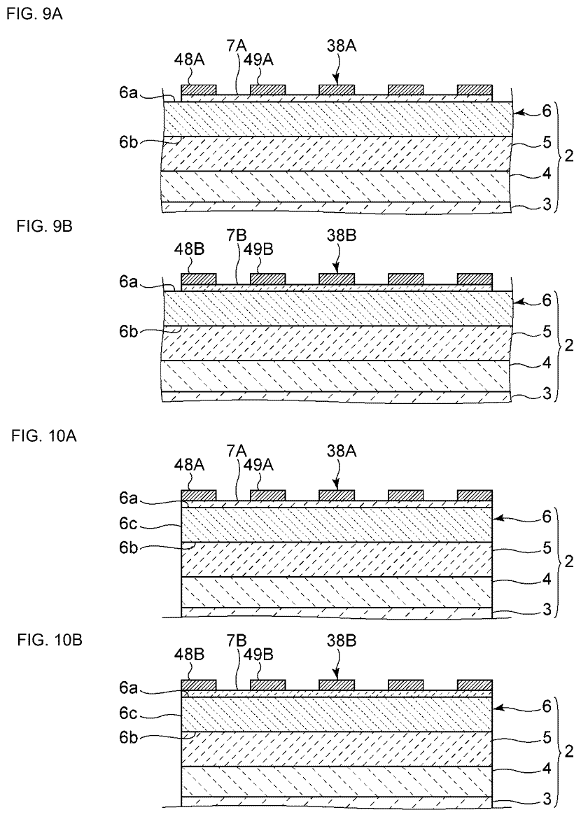

FIG. 9A is a schematic elevational cross-sectional view of a first acoustic wave resonator in a fourth example embodiment of the present invention. FIG. 9B is a schematic elevational cross-sectional view of a second acoustic wave resonator in the fourth example embodiment.

As shown in FIGS. 9A and 9B, the layout of the first dielectric film 7A and the second dielectric film 7B on the first principal surface 6a of the piezoelectric layer 6 of the present example embodiment is different from that of the first example embodiment. In the present example embodiment, the shapes of multiple first electrode fingers 48A and multiple second electrode fingers 49A of a first IDT electrode 38A, and the shapes of multiple first electrode fingers 48B and multiple second electrode fingers 49B of a second IDT electrode 38B are also different from those of the first example embodiment. Except for the above-described points, the acoustic wave apparatus of the present example embodiment has the same or substantially the same configuration as that of the acoustic wave apparatus 10 of the first example embodiment.

As shown in FIG. 9A, a side surface of each electrode finger of the first IDT electrode 38A extends parallel or substantially parallel direction to the first principal surface 6a of the piezoelectric layer 6. Likewise, as shown in FIG. 9B, a side surface of each electrode finger of the second IDT electrode 38B extends parallel or substantially parallel to the normal direction to the first principal surface 6a of the piezoelectric layer 6.

As shown in FIG. 9A, an end edge portion in the acoustic wave propagating direction of the first dielectric film 7A and an end edge portion in the acoustic wave propagating direction of the first IDT electrode 38A overlap each other in plan view. To be more precise, the end edge portion in the acoustic wave propagating direction of the first dielectric film 7A and the end edge portion of the electrode finger located on the outermost side portion in the acoustic wave propagating direction of the first IDT electrode 38A overlap each other in plan view. Here, the expression “in plan view” in the present specification means an viewing the acoustic wave apparatus from a direction corresponding to an upper side in a schematic cross-sectional view such as FIG. 9A. In FIG. 9A, the first IDT electrode 38A side out of the piezoelectric layer 6 side and the first IDT electrode 38A side is the upper side, for example.

As shown in FIG. 9B, an end edge portion in the acoustic wave propagating direction of the second dielectric film 7B and an end edge portion in the acoustic wave propagating direction of the second IDT electrode 38B overlap each other in plan view. To be more precise, the end edge portion in the acoustic wave propagating direction of the second dielectric film 7B and the end edge portion of the electrode finger located on the outermost side portion in the acoustic wave propagating direction of the second IDT electrode 38B overlap each other in plan view.

The acoustic wave apparatus of the present example embodiment also has the configurations 1) and 2) as with the acoustic wave apparatus 10 of the first example embodiment. As such, the fractional band width of each acoustic wave resonator of the acoustic wave apparatus can easily be adjusted without causing an increase in size of the acoustic wave apparatus.

FIG. 10A is a schematic elevational cross-sectional view of a first acoustic wave resonator in a fifth example embodiment of the present invention. FIG. 10B is a schematic elevational cross-sectional view of a second acoustic wave resonator in the fifth example embodiment.

As shown in FIGS. 10A and 10B, the present example embodiment is different from the fourth example embodiment in that the first acoustic wave resonator and the second acoustic wave resonator include individual piezoelectric substrates 2, respectively. Here, the piezoelectric layer 6 in the first acoustic wave resonator has a side surface 6c. The side surface 6c is connected to the first principal surface 6a and to the second principal surface 6b. Likewise, the piezoelectric layer 6 in the second acoustic wave resonator also includes a side surface 6c. Except for the above-described points, the acoustic wave apparatus of the present example embodiment has the same or substantially the same configuration as that of the acoustic wave apparatus of the fourth example embodiment.

As shown in FIG. 10A, the end edge portion in the acoustic wave propagating direction of the first dielectric film 7A, the end edge portion in the acoustic wave propagating direction of the first IDT electrode 38A, and an end edge portion in the acoustic wave propagating direction of the piezoelectric layer 6 overlap one another in plan view. To be more precise, the end edge portion in the acoustic wave propagating direction of the first dielectric film 7A, the end edge portion of the electrode finger located on the outermost side portion in the acoustic wave propagating direction of the first IDT electrode 38A, and the side surface 6c of the piezoelectric layer 6 overlap one another in plan view.

As shown in FIG. 10B, the end edge portion in the acoustic wave propagating direction of the second dielectric film 7B, the end edge portion in the acoustic wave propagating direction of the second IDT electrode 38B, and the end edge portion in the acoustic wave propagating direction of the piezoelectric layer 6 overlap one another in plan view. To be more precise, the end edge portion in the acoustic wave propagating direction of the second dielectric film 7B, the end edge portion of the electrode finger located on the outermost side portion in the acoustic wave propagating direction of the second IDT electrode 38B, and the side surface 6c of the piezoelectric layer 6 overlap one another in plan view.

The acoustic wave apparatus of the present example embodiment also has the configurations 1) and 2) as with the acoustic wave apparatus of the fourth example embodiment. As such, the fractional band width of each acoustic wave resonator of the acoustic wave apparatus can easily be adjusted without causing an increase in size of the acoustic wave apparatus.

The first to fifth example embodiments have demonstrated examples in which the acoustic wave apparatus is a single filter. Nevertheless, an acoustic wave apparatus according to an example embodiment of the present invention may be a multiplexer that includes multiple filters. The first acoustic wave resonator and the second acoustic wave resonator may be included in different filters from each other. This example will be shown in a sixth example embodiment of the present invention.

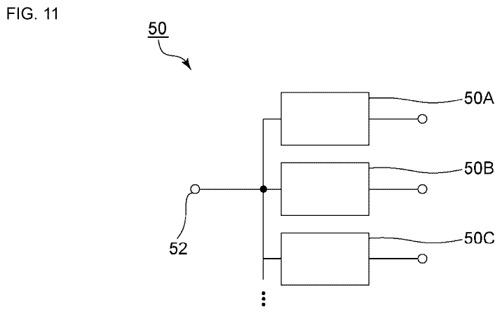

FIG. 11 is a schematic diagram of an acoustic wave apparatus according to the sixth example embodiment.

An acoustic wave apparatus 50 is a multiplexer. The acoustic wave apparatus 50 includes a common connection terminal 52, a first filter 50A, a second filter 50B, a third filter 50C, and other multiple filters. The first filter 50A, the second filter 50B, the third filter 50C, and the other multiple filters are connected in common to the common connection terminal 52. In the present example embodiment, the common connection terminal 52 is an antenna terminal, for example. Nonetheless, the common connection terminal 52 does not have to be the antenna terminal.

The first filter 50A, the second filter 50B, and the third filter 50C each include multiple acoustic wave resonators. The first filter 50A, the second filter 50B, and the third filter 50C have pass bands that are different from one another. Here, the acoustic wave apparatus 50, which is a multiplexer, only needs to include two or more filters. A circuit configuration in each filter of the acoustic wave apparatus 50 is not limited to a particular configuration.

The first filter 50A includes the multiple first acoustic wave resonators according to example embodiments of the present invention. The first filter 50A only needs to include at least one first acoustic wave resonator. In the meantime, the second filter 50B includes the multiple second acoustic wave resonators according to example embodiments of the present invention. The second filter 50B only needs to include at least one second acoustic wave resonator.

In the present example embodiment as well, each of the first dielectric film and the second dielectric film includes, for example, Li and Ta or includes Li and Nb as with the first example embodiment. Moreover, at least one of the piezoelectricity, the direction of polarization, or the crystal structure is different between the first dielectric film and the second dielectric film. As such, the fractional band width of each acoustic wave resonator of the acoustic wave apparatus 50 can easily be adjusted without causing an increase in size of the acoustic wave apparatus 50.

In the acoustic wave apparatus 50, the width of the pass band of the first filter 50A and the width of the pass band of the second filter 50B are different from each other. Moreover, in the present example embodiment, the first dielectric film to be used for the first acoustic wave resonator in the first filter 50A and the second dielectric film to be used for the second acoustic wave resonator in the second filter 50B can be selected as appropriate. Accordingly, the first filter 50A and the second filter 50B can be easily adjusted to have desired widths of the pass bands.

The thickness of the first dielectric film in the first acoustic wave resonator included in the first filter 50A and the thickness of the second dielectric film in the second acoustic wave resonator included in the second filter 50B are preferably different from each other. In this case, it is possible to adjust the fractional band width in each of the first acoustic wave resonator and the second acoustic wave resonator to a desired value more reliably. As such, the first filter 50A and the second filter 50B can be adjusted to have desired widths of the pass bands more reliably and easily.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave apparatus comprising:
a piezoelectric substrate including a piezoelectric layer including a first principal surface and a second principal surface opposed to each other;
a first IDT electrode and a second IDT electrode directly or indirectly on the first principal surface of the piezoelectric layer; and
a first dielectric film and a second dielectric film on at least one of the first principal surface or the second principal surface of the piezoelectric layer; wherein
a portion of the piezoelectric substrate including the first IDT electrode, the first IDT electrode, and the first dielectric film define a first acoustic wave resonator;
a portion of the piezoelectric substrate including the second IDT electrode, the second IDT electrode, and the second dielectric film define a second acoustic wave resonator;
each of the first dielectric film and the second dielectric film includes Li and Ta or includes Li and Nb; and
at least one of a piezoelectricity, a direction of polarization, or a crystal structure is different between the first dielectric film and the second dielectric film.

2. The acoustic wave apparatus according to claim 1, wherein the first dielectric film includes a LiTaOₓ film or a LiNbOₓ film, where x is a freely-selected positive number.

3. The acoustic wave apparatus according to claim 1, wherein the second dielectric film includes a LiTaO_{y} film or a LiNbO_{y} film, where y is a freely-selected positive number.

4. The acoustic wave apparatus according to claim 1, wherein
at least one of the first dielectric film or the second dielectric film includes Li and Nb; and
the piezoelectric layer includes Li and Nb.

5. The acoustic wave apparatus according to claim 1, wherein
at least one of the first dielectric film or the second dielectric film includes Li and Ta; and
the piezoelectric layer includes Li and Ta.

6. The acoustic wave apparatus according to claim 1, wherein
the first dielectric film is on the first principal surface of the piezoelectric layer; and
the first IDT electrode is indirectly on the first principal surface with the first dielectric film interposed between the first IDT electrode and the first principal surface.

7. The acoustic wave apparatus according to claim 6, wherein
the second dielectric film is on the first principal surface of the piezoelectric layer; and
the second IDT electrode is indirectly on the first principal surface with the second dielectric film interposed between the second IDT electrode and the first principal surface.

8. The acoustic wave apparatus according to claim 1, wherein
the first dielectric film is on the second principal surface of the piezoelectric layer; and
the first IDT electrode and the first dielectric film are opposed to each other with the piezoelectric layer interposed between the first IDT electrode and the first dielectric film.

9. The acoustic wave apparatus according to claim 8, wherein
the second dielectric film is on the second principal surface of the piezoelectric layer; and
the second IDT electrode and the second dielectric film are opposed to each other with the piezoelectric layer interposed between the second IDT electrode and the second dielectric film.

10. The acoustic wave apparatus according to claim 8, wherein
the piezoelectric substrate includes a support substrate; and
the first dielectric film is between the support substrate and the piezoelectric layer.

11. The acoustic wave apparatus according to claim 1, wherein thicknesses of the first dielectric film and the second dielectric film are different from each other.

12. The acoustic wave apparatus according to claim 1, wherein
the acoustic wave apparatus is a single filter including a plurality of acoustic wave resonators; and
the plurality of acoustic wave resonators include the first acoustic wave resonator and the second acoustic wave resonator.

13. The acoustic wave apparatus according to claim 1, wherein
the acoustic wave apparatus is a multiplexer including a plurality of filters; and
the first acoustic wave resonator and the second acoustic wave resonator are included in filters different from each other of the plurality of filters.

14. The acoustic wave apparatus according to claim 1, wherein the acoustic wave apparatus is configured to have a pass band in a range from about 2496 MHz to about 2690 MHz.

15. The acoustic wave apparatus according to claim 1, wherein the piezoelectric layer includes a piezoelectric single crystal layer including Li and Nb or Li and Ta.

16. The acoustic wave apparatus according to claim 1, wherein each of the first and second IDT electrodes includes electrode fingers including side surfaces inclined with respect to a direction normal to the first principal surface of the piezoelectric layer.

17. The acoustic wave apparatus according to claim 1, wherein each of the first and second IDT electrodes includes electrode fingers including side surfaces parallel or substantially parallel to a direction normal to the first principal surface of the piezoelectric layer.

18. The acoustic wave apparatus according to claim 12, wherein the plurality of acoustic wave resonators include a plurality of series arm resonators and a plurality of parallel arm resonators.

19. The acoustic wave apparatus according to claim 1, wherein each of the first and second IDT electrodes includes a Ti layer, an Al layer, and a Ti layer laminated in this order.

20. The acoustic wave apparatus according to claim 10, wherein the support substrate includes Si.
